(19) United States
(12) Patent Application Publication
(10) Pub. No.: US 2026/0090440 A1
(43) Pub. Date: Mar. 26, 2026

(54) MANUFACTURING METHOD FOR SEMICONDUCTOR DEVICE

(71) Applicant: KIOXIA CORPORATION, Tokyo (JP)

(72) Inventors: Tomonori FUJIMARU, Inabe Mie (JP); Kento KOMATSU, Yokkaichi Mie (JP); Shinichi KUSAKARI, Yokkaichi Mie (JP); Takahiro MIKUNI, Kamakura Kanagawa (JP); Soichi HOMMA, Yokkaichi Mie (JP)

(73) Assignee: KIOXIA CORPORATION, Tokyo (JP)

(21) Appl. No.: 19/077,120

(22) Filed: Mar. 12, 2025

(30) Foreign Application Priority Data
Sep. 20, 2024 (JP) 2024-164461

(51) Int. Cl. H01L 23/00

(52) U.S. Cl. CPC H10W 72/072; H10W 72/20; H10W 72/07233; H10W 72/07253; H10W 72/234

(57) ABSTRACT

A manufacturing method for a semiconductor device according to an embodiment includes a first step deforming a bump of a semiconductor element by applying a first load to the semiconductor element to press the bump onto a circuit board and applying either no ultrasonic vibration or ultrasonic vibration with a first strength to the bump and a second step, after the first step, bonding the bump to a pad of the circuit board by applying a second load to the semiconductor element to press the bump and applying ultrasonic vibration with a second strength stronger than the first strength to the bump.

### CROSS-REFERENCE TO RELATED APPLICATION

This application is based upon and claims the benefit of priority from Japanese Patent Application No. 2024-164461, filed on Sep. 20, 2024, the entire contents of which are incorporated herein by reference.

### FIELD

Embodiments described herein relate generally to a manufacturing method for a semiconductor device.

### BACKGROUND

In semiconductor devices employing flip-chip technology, applying ultrasonic vibration enables the connection between a substrate and a bump on the flip-chip. Studies are ongoing regarding techniques to bond a flip-chip with a circuit board in semiconductor devices utilizing NAND memory chips as well.

### BRIEF DESCRIPTION OF THE DRAWINGS

FIG. 1 is a flowchart for a manufacturing method for a semiconductor device;

FIG. 2 is a partial schematic diagram of a semiconductor device;

FIG. 3 shows profiles of the load strength, ultrasonic strength, and bump deformation height during a manufacturing method for a semiconductor device;

FIG. 4 is a schematic diagram relating to a manufacturing method for a semiconductor device;

FIG. 5 is a schematic diagram relating to a manufacturing method for a semiconductor device;

FIG. 6 is a schematic diagram relating to a manufacturing method for a semiconductor device;

FIG. 7 shows profiles of load strength, ultrasonic strength, and bump deformation height during a manufacturing method for a semiconductor device;

FIG. 8 shows profiles of load strength, ultrasonic strength, and bump deformation height during a manufacturing method for a semiconductor device;

FIG. 9 shows profiles of load strength, ultrasonic strength, and bump deformation height during a manufacturing method for a semiconductor device;

FIG. 10 is a schematic diagram relating to a manufacturing method for a semiconductor device;

FIG. 11 is a flowchart for a manufacturing method for a semiconductor device;

FIG. 12 shows profiles of load strength, ultrasonic strength, and bump deformation height during a manufacturing method for the semiconductor device;

FIG. 13 is a schematic diagram relating to a manufacturing method for a semiconductor device;

FIG. 14 is a flowchart for a manufacturing method for a semiconductor device;

FIG. 15 shows profiles of load strength, ultrasonic strength, and bump deformation height during a manufacturing method for a semiconductor device;

FIG. 16 is a schematic diagram relating to a manufacturing method for the semiconductor device;

FIG. 17 is a flowchart for a manufacturing method for a semiconductor device;

FIG. 18 shows profiles of load strength, ultrasonic strength, and bump deformation height during a manufacturing method for the semiconductor device;

FIG. 19 is a schematic diagram relating to a manufacturing method for a semiconductor device;

FIG. 20 is a flowchart for a manufacturing method for a semiconductor device;

FIG. 21 is a schematic diagram relating to a manufacturing method for a semiconductor device; and

FIG. 22 is a schematic diagram relating to a manufacturing method for a semiconductor device.

### DETAILED DESCRIPTION

A manufacturing method for a semiconductor device according to an embodiment includes a first step deforming a bump of a semiconductor element by applying a first load to the semiconductor element to press the bump onto a circuit board and applying either no ultrasonic vibration or ultrasonic vibration with a first strength to the bump and a second step, after the first step, bonding the bump to a pad of the circuit board by applying a second load to the semiconductor element to press the bump and applying ultrasonic vibration with a second strength stronger than the first strength to the bump.

In this specification, several elements are given a plurality of expression examples. These expression examples are merely examples, and do not deny that the above-described elements are expressed by other expressions. An element to which a plurality of expressions is not given may also be expressed by another expression.

The drawings are schematic, and a relationship between a thickness and a plane dimension, a ratio between thicknesses of layers, and the like may be different from actual relationship and ratios. In addition, the drawings may include portions having different dimensional relationships and ratios. In the drawings, some reference numerals may be omitted.

### First Embodiment

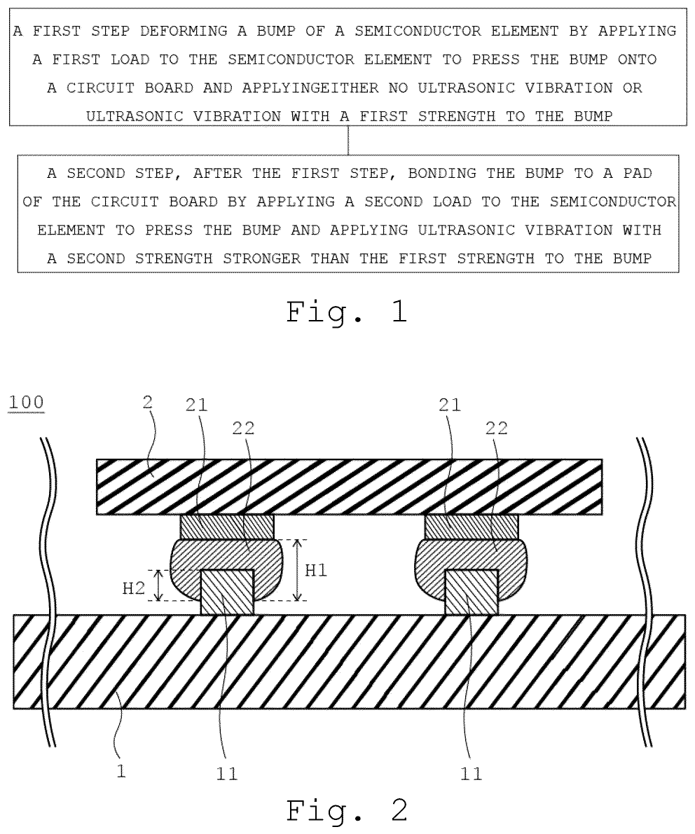

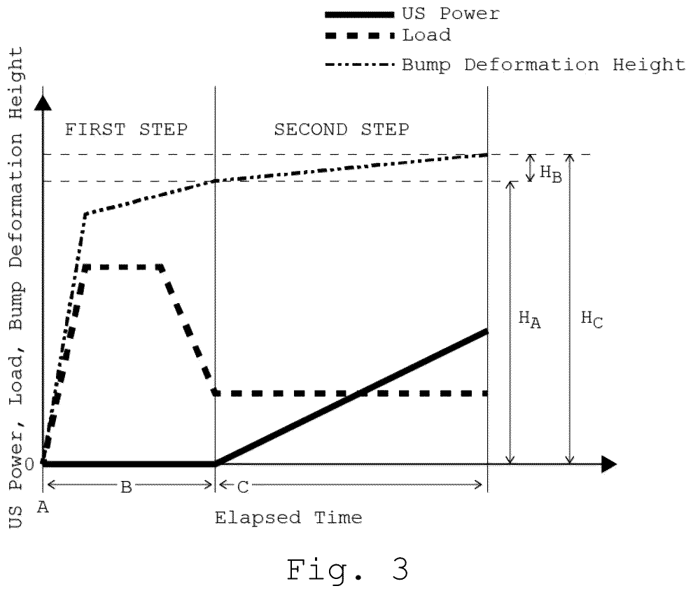

The first embodiment relates to a manufacturing method for a semiconductor device. FIG. 1 shows a flowchart of the manufacturing method for the semiconductor device. FIG. 2 shows a partial schematic diagram of the semiconductor device 100 according to this embodiment. The semiconductor device 100 according to this embodiment is a semiconductor package mounting one or more semiconductor elements, selected from a group consisting of a logic unit, a control unit, and a memory unit. It should be noted that all the schematic diagrams in this embodiment are cross-sectional views.

The semiconductor device 100 comprises a circuit board 1 and a semiconductor element 2. The circuit board 1 comprises a pad(s) 11. The semiconductor element 2 comprises an electrode(s) 21 and a bump(s) 22.

Preferable numerical ranges and the like of the first embodiment are common to other embodiments.

The circuit board 1 is a supporting substrate for the semiconductor element 2. The circuit board 1 is specifically, for example, a multi-layered circuit board. The circuit board 1 is electrically connected to the semiconductor element 2 via the pad 11. The circuit board 1 includes an aspherical electrode(s) such as a solder ball(s) unshown in drawings for connecting an external device with the semiconductor device 100.

The pad 11 is an electric conductor composed of, for example, Cu, Ni/Au, or Ni/Pd/Au. The width of the pad 11 is, for example, 20 [μm] or more and 30 [μm] or less, and the height is, for example, 10 [μm] or more and 20 [μm] or less.

The semiconductor element 2 is, for example, a logic element or a memory element. The semiconductor element 2 is connected by a flip-chip method. An electrode 21 of the semiconductor element 2 has a bump 22 provided thereon. The semiconductor element 2 is connected to the circuit board 1 through the bump 22.

The bump 22, for example, is solder and includes one or more metal elements selected from the group consisting of Sn, Ag, Cu, Ni, Pb, Bi, and In.

For example, the electrode 21 is a Cu pillar of the semiconductor element 2.

The semiconductor element 2 is a bare chip or a semiconductor device sealed with a mold. The bump 22 of the semiconductor element 2, which is a bare chip or a semiconductor device sealed with a mold, is connected to the circuit board 1.

It is preferable that the semiconductor device 100 includes other semiconductor devices. When the semiconductor device 100 is a memory device, the other semiconductor devices are NAND memory chips, and the semiconductor element 2 is a controller chip that controls reading, writing, and erasing of the NAND memory chips.

The height H1 of the bump 22 is the height of the bump 22 after performing the manufacturing method for the semiconductor device 100 according to the embodiment. The shape-deformed height H2 (collapsed height) is the height of the bump 22 that has been deformed in the manufacturing method for the semiconductor device 100, including the first embodiment and other embodiments. It is preferable that the height H1 etc. of the bump 22 be the height of the bump 22 on the center side rather than the outer peripheral side of the semiconductor element 2.

The shape-deformed height H2 is preferably 40% or more and 72% or less of H1, more preferably 48% or more and 64% or less of H1, and even more preferably 52% or more and 60% or less of H1.

The shape-deformed height H2 is preferably 10 [μm] or more and 18 [μm] or less, more preferably 12 [μm] or more and 16 [μm] or less, and even more preferably 13 [μm] or more and 15 [μm] or less.

The shape-deformed height H2 is preferably 40% or more and 72% or less of H1 and 10 [μm] or more and 18 [μm] or less, more preferably 48% or more and 62% or less of H1 and 12 [μm] or more and 16 [μm] or less, and even more preferably 52% or more and 60% or less of H1 and 13 [μm] or more and 15 [μm] or less.

The manufacturing method of the semiconductor device 100 according to the flowchart in FIG. 1 comprises: a first step deforming a bump of a semiconductor element 2 by applying a first load P1 to the semiconductor element 2 to press the bump 22 onto a circuit board 1 and applying either no ultrasonic vibration or ultrasonic vibration with a first strength US1 to the bump 22; and a second step, after (following) the first step, bonding the bump 22 to a pad of the circuit board by applying a second load to the semiconductor element to press the bump and applying ultrasonic vibration with a second strength stronger than the first strength to the bump 22.

It is preferable that flux is applied to the bump 22 and/or the pad 11 before the first step so that flux is provided on the surface of the connection portion between the bump 22 and the pad 11.

In the first step, the bump 22 is mainly deformed (deformed so that the shape of the bump is collapsed), while in the second step, the bump 22 and the pad 11 are mainly bonded.

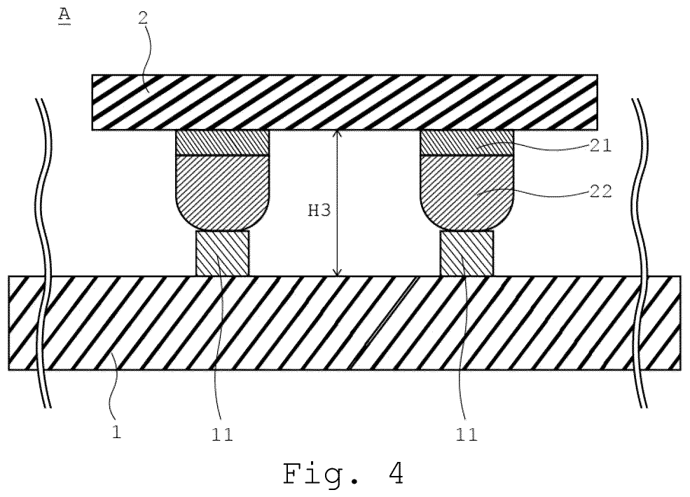

The manufacturing method for the semiconductor device 100 of the first embodiment will be described with reference to FIG. 2, which is a partial schematic diagram of the semiconductor device 100, FIG. 3, which shows profiles of the load strength, ultrasonic strength (US power), and bump deformation height during the manufacturing method for the semiconductor device 100 and FIGS. 4 to 6, which are schematic diagrams illustrating the manufacturing method for the semiconductor device 100.

In the first embodiment, two methods will be described separately for the first step: a method in which ultrasonic vibration is not applied to the bump 22, and a method in which ultrasonic vibration with a first strength US1 is applied to the bump 22. First, the method in which no ultrasonic vibration is applied to the bump 22 in the first step will be described, followed by a description of the method in which ultrasonic vibration with a first strength US1 is applied to the bump 22.

The horizontal axis of the profile in FIG. 3 shows the elapsed time during the process of connecting the semiconductor element 2 to the circuit board 1. The vertical axis of the profile shows the strength of the load applied to the semiconductor element 2 with a dashed line, the strength of ultrasonic vibration (US power) applied to the bump 22 with a thick solid line, and the deformation height of the bump 22 with a double dash-dot line.

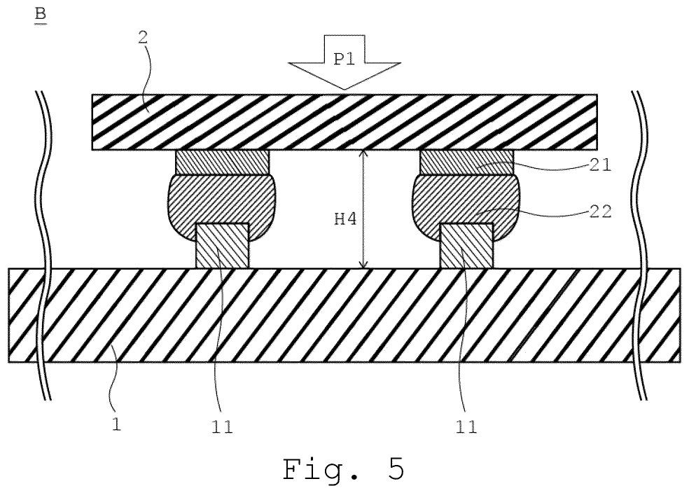

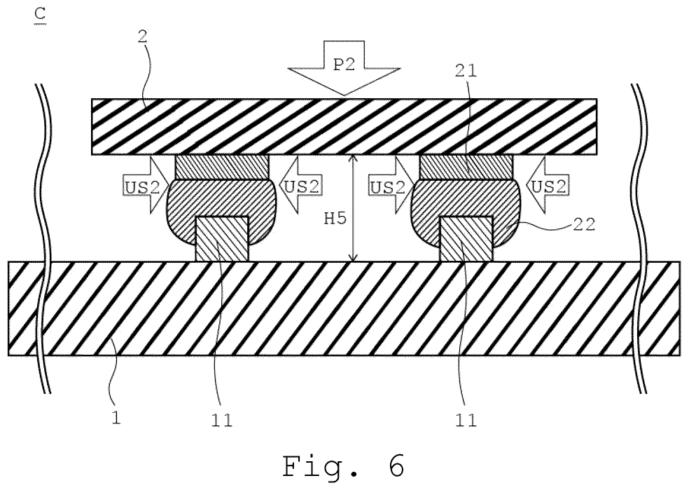

FIG. 4 illustrates a schematic diagram relating to the manufacturing method for the semiconductor device 100 at time A (the beginning of the first step) when the elapsed time in FIG. 3 is zero. FIG. 5 illustrates a schematic diagram relating to the manufacturing method for the semiconductor device 100 at time B (from the middle to the end of the first step) when the elapsed time in FIG. 3 is B. FIG. 6 illustrates a schematic diagram relating to the manufacturing method for the semiconductor device 100 at time C (from the middle to the end of the second step) when the elapsed time in FIG. 3 is C. FIG. 3 shows the height H_{A} the bump 22 deformed during the first step. FIG. 3 also shows the height H_{B} of the bump 22 deformed during the second step. In addition, FIG. 3 shows the total height H_{C} of the bump 22 deformed during the process of this embodiment.

In the first embodiment, the total height H_{C} of deformation of the bump 22 from the start to the end of the process for bonding the bump 22 and the pad 11 is the sum of the heights of deformation (H_{A}+H_{B}) in the first step and the second step. However, in other embodiments, the total height HC of deformation of the bump 22 includes the height of deformation in processes other than the first step and the second step.

Referring to the schematic diagrams relating to the manufacturing method for the semiconductor device shown in FIG. 4 and FIG. 5, the first step will be explained. In the first step, a load is applied to the semiconductor element 2 to press the bump 22 of the semiconductor element 2 onto the circuit board 1, deforming the bump 22 without applying ultrasonic vibration. Before the first step, neither a load nor ultrasonic vibration is applied. For example, it is preferable to use a collet that vibrates ultrasonically for a chuck part for sucking and placing the semiconductor element 2 on the circuit board 1. The strength of the load applied by the collet and the output of the ultrasonic vibration can be adjusted to adjust the load and the strength of the ultrasonic vibration in the embodiment.

As shown in the schematic diagram of FIG. 4, the first step is started from a state where the positions of the bump 22 and the pad 11 are aligned. By applying the first load P1 to the semiconductor element 2 in the direction facing the circuit board 1, as shown in the schematic diagram of FIG. 5, the bump 22 is deformed. In the first embodiment of the first step, the bump 22 is deformed by applying the load without applying ultrasonic vibration to the bump 22.

The height of the bump 22 before deformation is, for example, 20 [μm] or more and 40 [μm] or less. The diameter of the bump 22 before deformation is, for example, 30 [μm] or more and 50 [μm] or less. The height of the bump 22 and other dimensions can be measured by observing and measuring the distance between the semiconductor element 2 and the circuit board 1 during manufacturing.

The first load P1 is modulated over time from the start of the first step, increasing continuously or intermittently until it reaches a desired load strength. After reaching the desired load strength, the load strength is kept constant, then weakened, kept constant again, or weakened. In the profile shown in FIG. 3, after the first load P1 reaches the desired load strength, the load strength is weakened to the second load P2 of the second step.

Since the bump 22 deforms during the first step by applying a force with strength of the first load P1, the distance (distance between the plane portion of the semiconductor element 2 and the plane portion of the circuit board 1) H3 between the semiconductor element 2 and the circuit board 1 in FIG. 4 shrinks to the distance H4 shown in FIG. 5. The height HA of the bump 22 changing during the first step is calculated as [distance H3 at the start of the first step]−[distance H4 at the end of the first step].

Referring to the schematic diagram in FIG. 6, the second step will be explained. In the second step, a second load P2 is applied to the semiconductor element 2 to press the bump 22 of the semiconductor element 2 onto the circuit board 1. Ultrasonic vibration with a second strength US2 is applied to the bump 22 to bond the bump 22 to the pad 11 of the circuit board 1. In the second step, both load and ultrasonic vibration are applied to bond the bump 22 of the semiconductor element 2 to the pad 11 of the circuit board 1.

The bump 22 of the semiconductor element 2 onto the circuit board 1 with the second load P2 presses, for example, at a constant load from the start of the second step. The second load P2 may be a constant load or a varying load. A maximum value of the second load P2 is set to be weaker than a maximum value of the first load P1.

Since the bump 22 is deformed during the first step, even when a load with the same strength as in the first step is applied during the second step, the change in the height of the bump 22 during the second step will be smaller than the change in the height of the bump 22 during the first step.

In the second step, ultrasonic vibration with the second strength US2 is applied to the bump 22 to heat the bump 22 and raise the processing temperature at the interface between the bump 22 and the pad 11, thereby bonding the bump 22 and the pad 11.

It is preferable that the ultrasonic vibration applied to the bump 22 is applied from the side of the semiconductor element 2 to the bump 22.

The second strength US2 gradually increases in strength over time, preferably linearly, from the start of the second step. Once the desired strength is reached, the strength of the ultrasonic vibration can be held constant or reduced after a period of constant strength. In the second step, ultrasonic vibration may be applied at a maximum value of the second strength US2 from the start of the second step.

During the second step, applying the ultrasonic vibration with the second strength US2 and the second load P2 can cause deformation of the bump 22. The distance (H4) between the semiconductor element 2 and the circuit board 1 in FIG. 5 may shrink to the distance (H5) shown in FIG. 6. The height H_{B} of the bump 22 changing during the second step is calculated as [distance H4 at the end of the first step]−[distance H5 at the end of the second step]. The height H_{B} of the bump 22 changing during the second step may be zero.

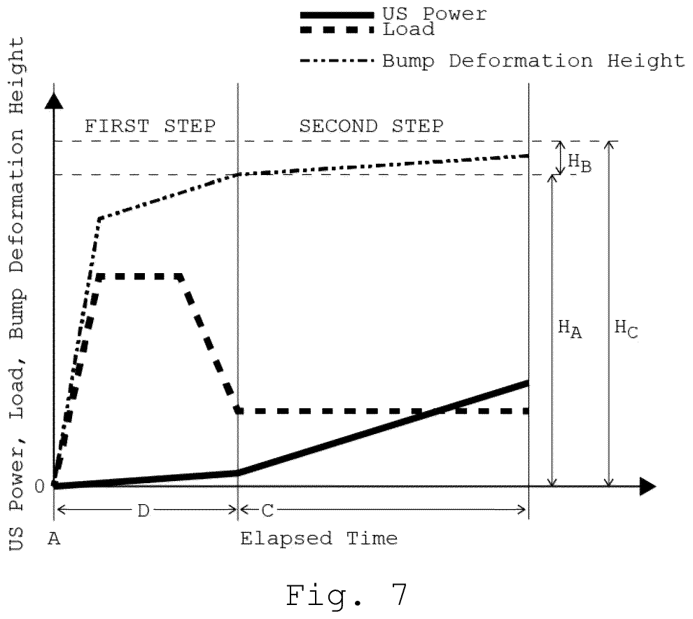

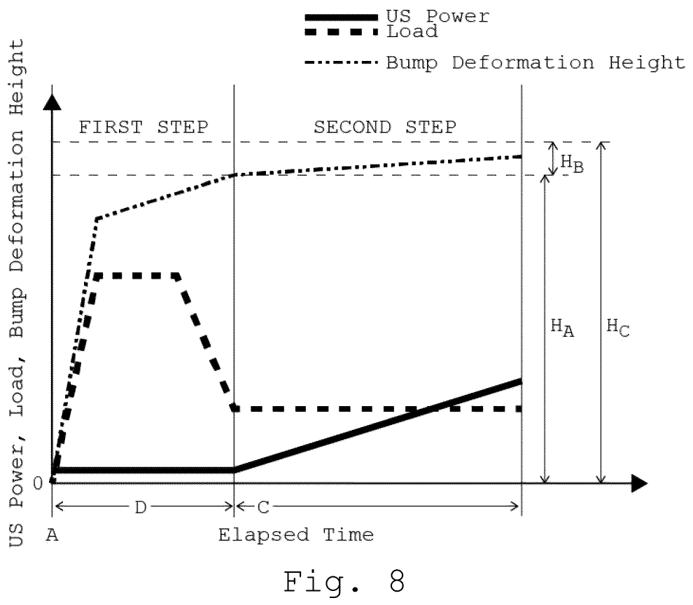

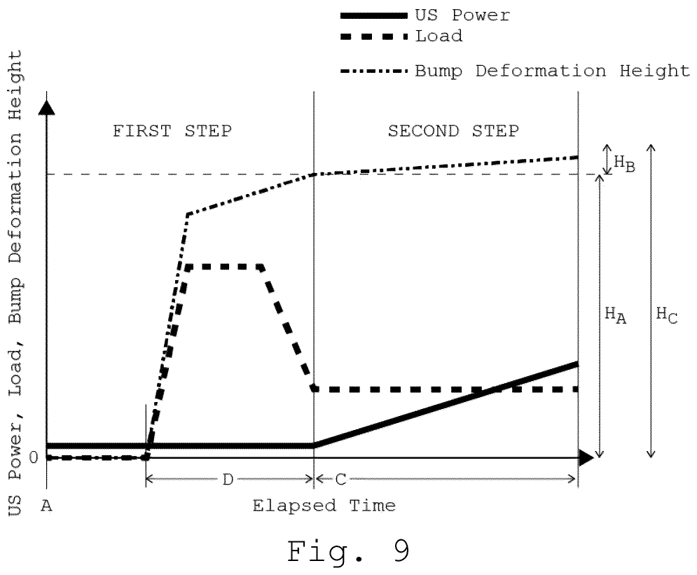

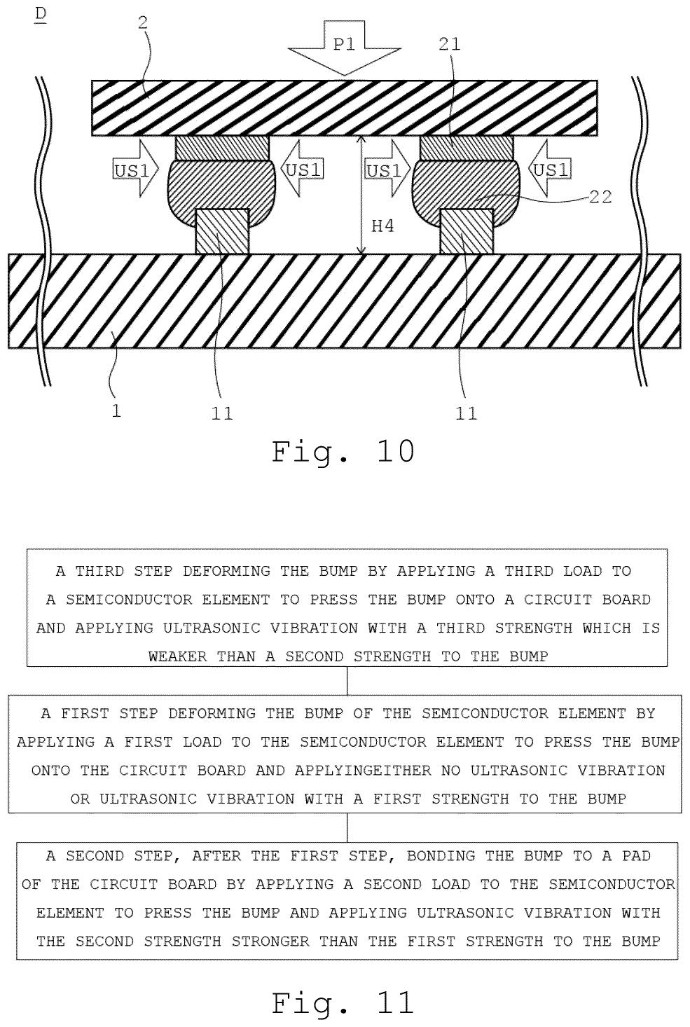

The process of applying ultrasonic vibration with the first strength US1 to the bump 22 will be described below, referencing FIG. 7, FIG. 8, and FIG. 9 which illustrate profiles of load, ultrasonic strength, and bump height deformation in the manufacturing method for the semiconductor device 100. FIG. 10 illustrates a schematic diagram relating to the manufacturing method for the semiconductor device 100.

The profile shown in FIG. 7 differs from that in FIG. 3 in terms of applying ultrasonic vibration with the first strength US1 to the bump 22 during the first step. Except for the ultrasonic vibration during the first step, the profiles in FIG. 3 and FIG. 7 are the same or like.

The profile shown in FIG. 8 is a variant of the profile shown in FIG. 7. Except for the ultrasonic vibration during the first step, the profiles in FIG. 7 and FIG. 8 are the same or like.

The profile shown in FIG. 9 is a variant of the profile shown in FIG. 7. Except for the ultrasonic vibration during the first step, the profiles in FIG. 7 and FIG. 9 are the same or like.

During the first step, as illustrated in a schematic diagram of FIG. 10, ultrasonic vibration with the first strength US1 is applied to the bump 22 while applying a first load P1 to the semiconductor element 2. This presses the bump 22 onto the circuit board 1 and deforms the bump.

During the first step, applying ultrasonic vibration with the first strength US1 to the bump 22 while applying the load of the first load P1 deforms the bump 22. As a result, the distance H3 between the semiconductor element 2 and the circuit board 1 in FIG. 4 is reduced to the distance H4 shown in FIG. 10. The height HA of the deformation of the bump 22 during the first step is calculated as [the distance H3 at the beginning of the first step]−[the distance H4 at the end of the first step (FIG. 10).

The first strength US1 is modulated over time from the start of the first step, continuously or intermittently, so that the ultrasonic vibration becomes stronger and reaches a desired ultrasonic vibration strength. After reaching the desired strength, the first step may end, the ultrasonic vibration strength may be kept constant, or the ultrasonic vibration strength may be reduced. The first strength US1 may also be a constant strength that is not modulated over time or is not modulated practically. In the profile of FIG. 7, the first strength US1 increases linearly in ultrasonic vibration strength.

As a variant of the profile shown in FIG. 7, ultrasonic vibration with the first strength US1, which is weaker than the second strength US2 in the second step, may be applied to the bump 22 as shown in the profile of FIG. 8. By applying a constant weak first strength US1 in the first step, it is possible to further strengthen the bond.

Furthermore, as shown in the profile of FIG. 9, ultrasonic vibration with the first strength US1 may be applied before the first step without applying any load. In other words, ultrasonic vibration may be applied before applying the first load P1. The time duration for applying ultrasonic vibration with the first strength US1 to the bump 22 before starting to apply the first load P1 in the first step is set to 0.1 [sec] or more and 1.0 [sec] or less. By applying ultrasonic vibration with the first strength US1 to the bump 22 before starting to apply the first load P1 in the first step, it is possible to further strengthen the bond. In the profile of FIG. 9, when ultrasonic vibration is applied to the bump 22 in the first step, it is preferable to apply ultrasonic vibration with the first strength US1 to the bump without applying any first load before applying the first load P1.

It is preferable that the first load P1 is stronger than the second load P2 (the load integral value of the first load P1 is larger than the load integral value of the second load P2).

The maximum value of the first load P1 is 100% or more and 250% or less, more preferably 110% or more and 200% or less, even more preferably 120% or more and 140% or less of the maximum value of the second load P2.

It is preferable that the second strength US2 of ultrasonic vibration in the second step is stronger than the first strength US1 of ultrasonic vibration in the first step (the integral value of ultrasonic vibration strength of the second strength US2 is larger than the integral value of ultrasonic vibration strength of the first strength US1). Preferably, the integral value of ultrasonic vibration strength of the second strength US2 is 1500% or more and 2000% or less of the integral value of ultrasonic vibration strength of the first strength US1.

A maximum value of the first strength US1 is preferably 0% or more and 70% or less, more preferably 0% or more and 50% or less, and even more preferably 0% or more and 30% or less of the maximum value of the second strength US2.

It is preferable that the average value of the first strength US1 is 0% or more and 70% or less of the average value of the second strength US2. More preferably, it is 0% or more and 50% or less. Even more preferably, it is 0% or more and 30% or less.

It is preferable that the first load P1 is a strong load and deforms the bump 22 significantly in the first step where ultrasonic vibration is not applied or weak strength ultrasonic vibration (first strength US1) is applied. By significantly deforming the bump 22 in the first step, it is possible to suppress the formation of protrusions that are easily formed on the surface of the bump 22 due to ultrasonic vibrations because ultrasonic vibrations are not being applied or weak ultrasonic vibrations are being applied.

For example, if a load for deforming the bump 22 and strong ultrasonic vibration for bonding are applied to the bump 22 simultaneously, the shape of the bump 22 changes significantly, making it easy for the bump 22 to contact the prepreg on the surface of the circuit board 1 or for large protrusions to form on the surface of the bump 22.

When the bump 22 contacts the prepreg or the like on the surface of the circuit board 1, a short circuit will not occur because the prepreg is an insulator. However, ultrasonic vibrations are more likely to propagate to the side of the circuit board 1, making it difficult for the intended ultrasonic vibrations to reach the bump 22 sufficiently. This can result in insufficient bonding between the bump 22 and the pad 11.

Furthermore, when applying strong loads that significantly collapse the bump 22 while simultaneously applying strong ultrasonic vibrations, large protrusions are likely to form on the surface of the bump 22, for example, solder. If large protrusions form on the bump 22, they may come into contact with each other and cause a short circuit. Short circuits caused by the bump 22 or a predisposition to short circuits can lead to a decrease in yield and reliability.

The height H_{A} of the bump 22, which changes during the first step, is preferably 30% or more, more preferably 50% or more, and even more preferably 60% or more of the total height (HA+HB) of the bump 22 deformed during the first step and the second step.

The height H_{A} of the bump 22, which changes during the first step, is preferably 30% or more and 100 % or less, more preferably 50% or more and 100% or less, and even more preferably 60% or more and 100% or less of the total height (H_{A}+H_{B}) of the bump 22 deformed during the first step and the second step.

The height H_{A} of the bump 22, which changes during the first step, is preferably 30% or more and 95 % or less, more preferably 50% or more and 95 or less, and even more preferably 60% or more and 95 % or less of the total height (H_{A}+H_{B}) of the bump 22 deformed during the first step and the second step.

The height H_{B} of the bump 22, which deforms in the second step, is preferably 0% or more and 200% or less, more preferably 0% or more and 100% or less, and even more preferably 0% or more and 75% or less of the height H_{A} of the bump 22 that deforms in the first step.

The height H_{B} of the bump 22, which deforms in the second step, is preferably more than 0% and 200% or less, more preferably more than 0% and 100% or less, and even more preferably more than 0% and 75% or less of the height HA of the bump 22 that deforms in the first step.

During the first step and the second step, the temperature of the bump 22 is preferably equal to or below the melting point of the bump 22. The temperature of the bump 22 in the second step is preferably higher than the temperature of the bump 22 in the first step.

By significantly deforming the bump 22 in the first step, which involves applying no ultrasonic vibration or weak first strength US1 ultrasonic vibration to the bump 22, the deformation height of the bump 22 can be reduced in the second step. This allows suppression of unintended deformation of the bump 22 even when strong second strength US2 ultrasonic vibration is applied.

In this embodiment, by dividing the process primarily into the first step that mainly deforms the bump 22 and the second step that mainly bonds the bump 22 to the pad 11, unintended large deformation of the bump 22 can be suppressed in both the first step and the second step. This contributes to improved yield and reliability.

### Second Embodiment

The second embodiment relates to a manufacturing method for a semiconductor device 100. The second embodiment is a variant in which a third step is added to the manufacturing method for the semiconductor device 100 of the first embodiment. The explanation of the content common to the second embodiment and the first embodiment will be omitted.

FIG. 11 shows a flowchart of the manufacturing method for the semiconductor device 100. The manufacturing method for the semiconductor device 100 according to the second embodiment further includes a third step, before the first step, deforming the bump 22 by applying a third load P3 to the semiconductor element 2 to press the bump 22 onto the circuit board 1 and applying ultrasonic vibration with a third strength US3 which is weaker than the second strength US2 to the bump 22.

It is preferable that flux is provided on the surface of the connection part between the bump 22 and the pad 11. This can be achieved, for example, by applying flux to the bump 22 and/or the pad 11 before the third step.

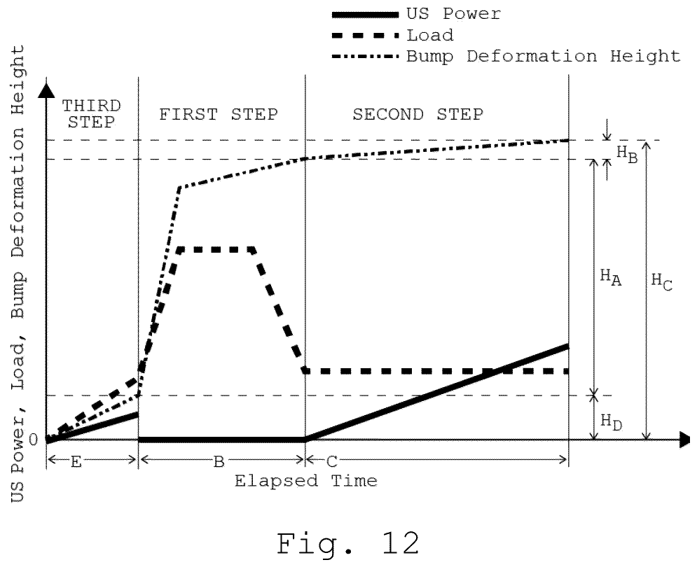

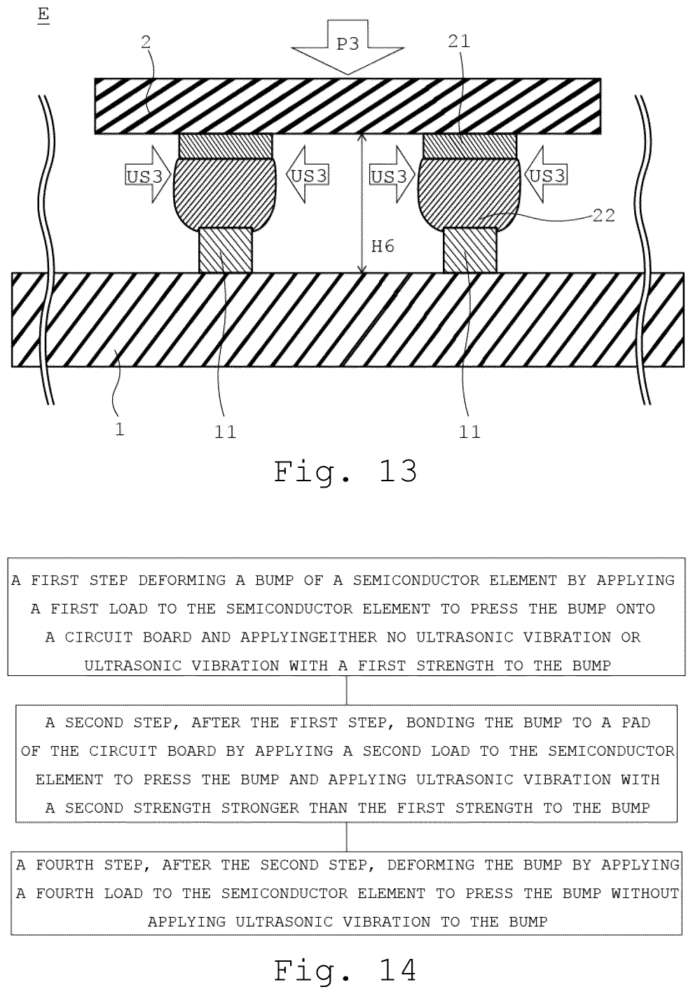

Regarding the manufacturing method for the semiconductor device 100 according to the second embodiment, referring to FIG. 12 showing a profile of the load strength, the ultrasonic strength (US power), and the deformation height of the bump 22 in the manufacturing method for the semiconductor device 100 and FIG. 13 illustrating a schematic diagram relating to the manufacturing method for the semiconductor device 100 will be explained. The profile in FIG. 12 also shows the profile of the load strength, the ultrasonic strength (US power), and the deformation height of the bump 22 in the third step.

FIG. 13 shows a schematic diagram of FIG. 12 at time E (from the middle to the end of the third step). In FIG. 12, shows the height H_{A} of the bump 22 deformed during the first step, the height H_{B} of the bump 22 deformed during the second step, a height H_{D} of the bump 22 deformed during the third step and the total height H_{C} of deformation of the bump 22 in the processes of the second embodiment (H_{C}(=H_{A}+H_{B}+H_{D})).

The third step starts from the state where the positions of the bump 22 and the pad 11 shown in FIG. 4 are aligned. Then, a third load P3 is applied to the semiconductor element 2 in the direction facing the circuit board 1, and ultrasonic vibration with third strength US3 is applied to the bump 22, deforming the bump 22.

The third load P3 is modulated so that the load increases over time continuously or intermittently from the start of the third step, reaching the desired load strength. After reaching the desired load strength, the third step may be ended, or the load strength may be kept constant and then reduced, or kept constant, or reduced in the third step. In the profile shown in FIG. 12, the third load P3 linearly increases to the strength of the first load P1.

The third strength US3 is modulated so that ultrasonic vibration increases over time continuously or intermittently from the start of the third step, reaching the desired ultrasonic vibration strength. After reaching the desired strength, the third step may be ended, or the ultrasonic vibration strength may be kept constant and then reduced, or kept constant, or reduced. In the profile shown in FIG. 12, the third strength US3 linearly increases.

In the third step shown in the profile of FIG. 12, ultrasonic vibration with a fixed strength may be applied, as shown in the profile of the first step of FIG. 8. Specifically, ultrasonic vibration with a fixed third strength US3 may be applied to the bump 22 in the third step.

In the third step shown in the profile of FIG. 12, ultrasonic vibration with a fixed strength may be applied, as shown in the profile of the first step of FIG. 9. Specifically, ultrasonic vibration with a fixed third strength US3 may be applied to the bump 22 before applying the third load P3 in the third step.

In the third step, applying the third load P3 causes the bump 22 to deform, thereby reducing the distance H3 between the semiconductor element 2 and the circuit board 1 shown in FIG. 4 to the distance H6 shown in FIG. 13 between the semiconductor element 2 and the circuit board 1. The height HD of the bump 22 which changes during the third step is calculated as [distance H3 at the start of the third step]−[distance H6 at the end of the third step].

The height HD of the bump 22, which changes during the first step following the third step, is calculated as [distance H6 at the start of the first step]−[distance H4 at the end of the first step].

It is preferable that a maximum value of the third load P3 is smaller than the maximum value of the first load P1. The maximum value of the third load P3 is preferably 10% or more and 60% or less, more preferably 20% or more and 50% or less, and even more preferably 25% or more and 45% or less of the maximum value of the first load P1.

It is preferable that the maximum value of the third load P3 is smaller than the maximum value of the second load P2. The maximum value of the third load P3 is preferably 20% or more and 80% or less, more preferably 30% or more and 70% or less, and even more preferably 40% or more and 60% or less of the maximum value of the second load P2.

A maximum value of the third strength US3 is preferably 400% or more and 900% or less, more preferably 500% or more and 800% or less, and even more preferably 600% or more and 700% or less of the maximum value of the first strength US1.

The maximum value of the third strength US3 is preferably more than 0% and 100% or less, more preferably 0% or more (more than 0%) and 75% or less, and even more preferably 0% or more (more than 0%) and 50% or less of the maximum value of the second strength US2.

The average value of the third strength US3 is preferably 400% or more and 900% or less, more preferably 500% or more and 800% or less, and even more preferably 600% or more and 700% or less of the average value of the first strength US1.

The average value of the third strength US3 is more than 0% and 70% or less, more preferably 0% or more (more than 0%) and 75% or less, and even more preferably 0% or more (more than 0%) and 50% of the average value of the second strength US2.

The height H_{D} of the bump 22 which changes during the third step is 50% or less, more preferably 30% or less, and even more preferably 20% or less of the total height (H_{A}+H_{B}+H_{D}) of the bump 22 deformed during the first step, the second step, and the third step.

The height H_{D} of the bump 22 which changes during the third step is preferably 5% or more and 50% or less, more preferably 5% or more and 30% or less, and even more preferably 5% or more and 20% or less of the total height (H_{A}+H_{B}+H_{D}) the bump 22 deformed during the first step, the second step, and the third step.

The height HD of the bump 22 which changes during the third step is preferably 5% or more and 50% or less, more preferably 5% or more and 30% or less, and even more preferably 5% or more and 20% or less of the height H_{A} of the bump 22 deformed during the first step.

Preferably, the temperature of the bump 22 during the first step, the second step, and the third step is a temperature equal to or below the melting point of the bump 22. Preferably, the temperature of the bump 22 in the second step is higher than the temperature of the bump 22 in the first step.

Preferably, the bump 22 is slightly deformed in the third step, which applies ultrasonic vibration with weak strength (third strength US3) by the load P3 with a weak strength. By weakly bonding the bump 22 with the pad 11 before significantly deforming the bump 22 in the first step, the bump 22 and the pad 11 can be bonded more reliably after the first step.

### Third Embodiment

A third embodiment relates to a manufacturing method for a semiconductor device 100. The third embodiment is a variant in which a fourth step is added to the manufacturing method for the semiconductor device 100 according to the first embodiment. The fourth step can also be performed after (following) the second step of the second embodiment. Descriptions common to the third embodiment and the first and second embodiments will be omitted.

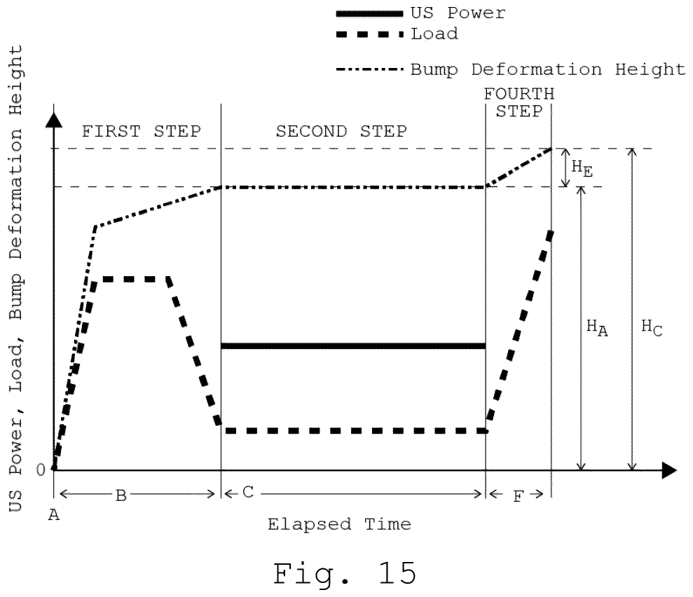

FIG. 14 shows a flowchart of the manufacturing method for the semiconductor device 100. The method manufacturing for a semiconductor device 100 according to the third embodiment further includes the fourth step, after the second step, deforming the bump 22 by applying a fourth load P4 to the semiconductor element 2 to press the bump 22 without applying ultrasonic vibration to the bump 22.

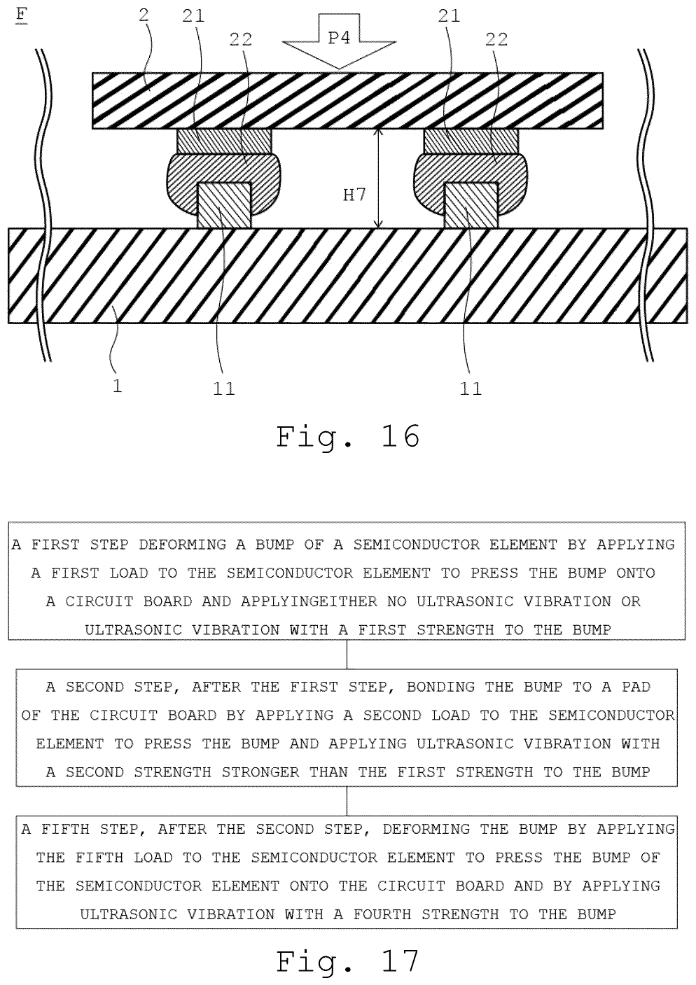

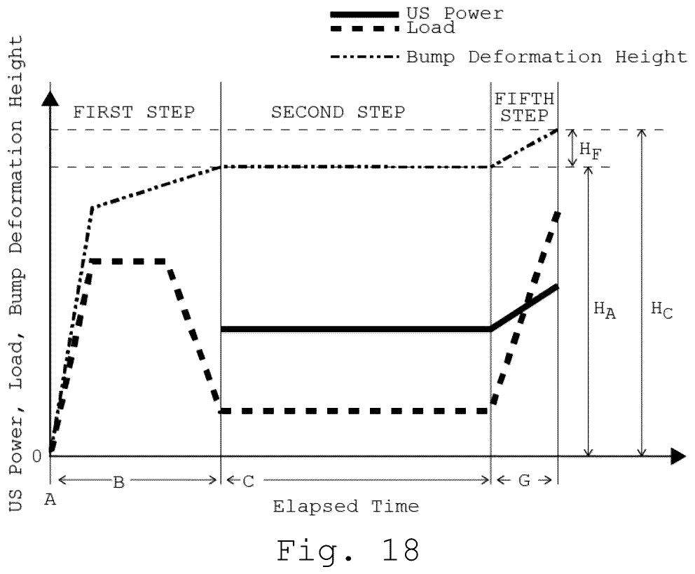

Regarding the manufacturing method for the semiconductor device 100 according to the third embodiment, referring to FIG. 15 showing a profile of the load strength, the ultrasonic strength (US power), and the deformation height of the bump 22 in the manufacturing method for the semiconductor device 100 and FIG. 16 illustrating the manufacturing method for the semiconductor device 100 will be explained. The profile in FIG. 15 also shows the profile of the load strength, the ultrasonic strength (US power), and the deformation height of the bump 22 in the fourth step.

FIG. 16 shows the schematic diagram relating to the manufacturing method for the semiconductor device 100 of at time F (from the start to the end of the fourth step) of FIG. 15. In FIG. 15, shows the height H_{A} of the bump 22 deformed during the first step, the height H_{B} of the bump 22 deformed during the second step, a height H_{E} of the bump 22 deformed during the fourth step and the total height H_{C} of deformation of the bump 22 in the processes of the second embodiment (H_{C}(=H_{A}+H_{B}+H_{E})).

The fourth step starts from the end timing of the second step. Then, a fourth load P4 is applied to the semiconductor element 2 in the direction facing the circuit board 1 without applying ultrasonic vibration to the bump 22, deforming the bump 22.

The fourth load P4 is modulated so that it increases over time continuously or intermittently from the start of the fourth step, reaching the desired load strength. After reaching the desired strength, the fourth step may be ended, or the load strength may be kept constant and then reduced, or kept constant, or reduced. In the profile shown in FIG. 15, the fourth load P4 linearly increases from the strength of the second load P2.

In the fourth step, applying the fourth load P4 causes the bump 22 to deform so that the shape of the bump 22 is collapsed, further reducing the height of the bump 22 that is bonded with the pad 11 in the fourth step. The height H_{E} of the bump 22 which changes during the fourth step is calculated as [distance H5 at the end of the second step]−[distance H7 at the end of the fourth step].

Preferably, a maximum value of the fourth load P4 is more than the maximum value of the first load P1. The maximum value of the fourth load P4 is 80% or more and 250% or less, more preferably 0% or more and 200% or less, and even more preferably 100% or more and 150% or less of the maximum value of the first load P1.

Preferably, the average value of the fourth load P4 is smaller than the average value of the first load P1. The average value of the fourth load P4 is preferably 80% or more and 250% or less, more preferably 90% or more and 200% or less, and even more preferably 100% or more and 150% or less of the average value of the first load P1.

Preferably, the maximum value of the fourth load P4 is more than the maximum value of the second load P2. The maximum value of the fourth load P4 is preferably 300% or more and 1200% or less, more preferably 500% or more and 1000% or less, and even more preferably 600% or more and 900% or less of the maximum value of the second load P2.

Preferably, the average value of the fourth load P4 is greater than the average value of the second load P2. The average value of the fourth load P4 is preferably 300% or more and 1200% or less, more preferably 500% or more and 1000% or less, and even more preferably 600% or more and 900% or less of the average value of the second load P2.

Preferably, ultrasonic vibration is not applied to the bump 22 during the fourth step.

In the third embodiment, the height HB of the bump 22 changing during the second step is preferably 0 [μm] or more and 7[μm] or less, more preferably 0 [μm] or more and 5 [μm] or less, and even more preferably 0 [μm] or more and 3 [μm] or less.

The height HE of the bump 22 which changes during the fourth step is less than 50%, more preferably 30% or less, and even more preferably 20% or less of the total height (H_{A}+H_{B}+H_{E}) of the bump 22 deformed during the first step, the second step, and the fourth step.

The height H_{E} of the bump 22 which changes during the fourth step is preferably 5% or more and less than 50%, more preferably 5% or more and 30% or less, and even more preferably 5% or more and 20% or less of the total height (H_{A}+H_{B}+H_{E}) of the bump 22 deformed during the first step, the second step, and the fourth step.

Te height H_{E} of the bump 22 which changes during the fourth step is 5% or more and less than 50%, more preferably 5% or more and 30% or less, even more preferably 5% or more and 20% or less of the height HA of the bump 22 deformed during the first step.

During the first step, the second step, and the fourth step, the temperature of the bump 22 is preferably a temperature equal to or below the melting point of the bump 22. The temperature of the bump 22 in the second step is preferably higher than the temperature of the bump 22 in the first step and higher than the temperature of the bump 22 in the fourth step.

It is preferable that the bump 22 is deformed slightly by applying with the fourth load P4 with a strong load. By further deforming (shape-collapsing) the bump 22 after bonding without applying ultrasonic vibration, it is possible to bond and deform the bump 22 and the pad 11 more reliably.

### Fourth Embodiment

A fourth embodiment relates to a manufacturing method for the semiconductor device 100. The fourth embodiment is a variant in which a fifth step is added to the manufacturing method for the semiconductor device 100 according to the first embodiment. The fifth step may also be performed after the second step of the second embodiment. The fifth step may also be performed before or after the fourth step of the third embodiment. For descriptions common to the fourth embodiment and the first to third embodiments, the explanation will be omitted.

FIG. 17 shows a flowchart of the manufacturing method for the semiconductor device 100. The manufacturing method for the semiconductor device 100 according to the fourth embodiment further includes a fifth step, after the second step, deforming the bump 22 by applying the fifth load P5 to the semiconductor element 2 to press the bump 22 of the semiconductor element 2 onto the circuit board 1 and by applying ultrasonic vibration with a fourth strength US4 to the bump 22.

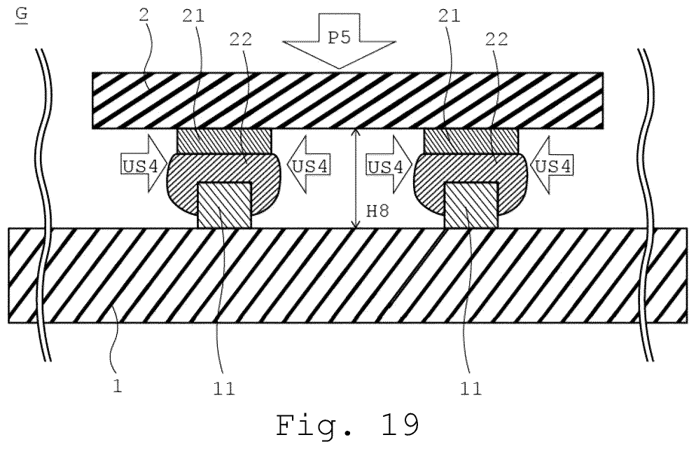

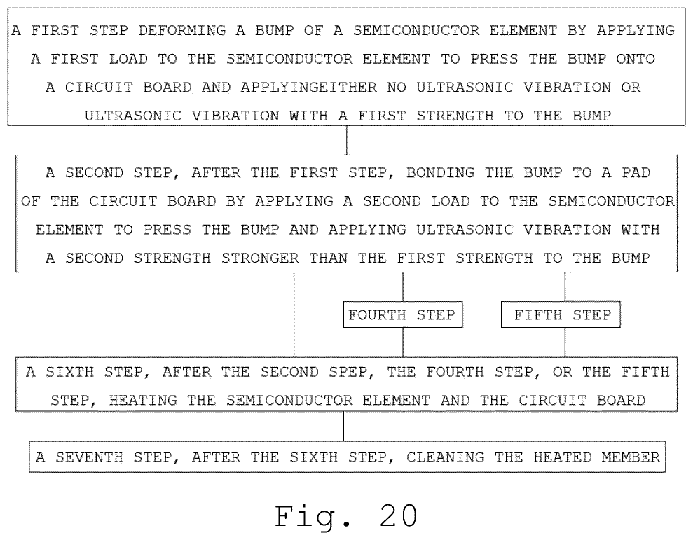

Regarding the manufacturing method for the semiconductor device 100 according to the fourth embodiment, referring to FIG. 18 showing a profile of the load strength, the ultrasonic strength (US power), and the deformation height of the bump 22 in the manufacturing method for the semiconductor device 100 and FIG. 19 illustrating the manufacturing method for the semiconductor device 100 will be explained. The profile in FIG. 18 also shows the profile of the load strength, the ultrasonic strength (US power), and the deformation height of the bump 22 in the fifth step.

FIG. 19 shows the schematic diagram relating to the manufacturing method for the semiconductor device 100 at time G in FIG. 18 (from the start of the fifth step to the end of the fifth step). FIG. 18 shows the bump height H_{A} deformed in the first step, the bump height H_{B} deformed in the second step, the bump height HF deformed in the fifth step, and the total bump height H_{C}(=H_{A}+H_{B}+H_{F}) deformed in the processes of the fourth embodiment.

The fifth step starts from the end of the second step. In the fifth step, the fifth load P5 is applied to the semiconductor element 2 to press the bump 22 of the semiconductor element 2 onto the circuit board 1, and ultrasonic vibration with a fourth strength US4 is applied to the bump 22 to deform the bump 22.

The fifth load P5 is modulated over time from the start of the fifth step so that the load becomes stronger continuously or intermittently. Once the desired load strength is reached, the fifth step may be ended, the load strength may be maintained constantly before weakening the load strength, or the load strength may be maintained constantly or be weakened. In the profile in FIG. 18, the fifth load P5 increases linearly starting from the strength of the second load P2.

The fourth strength US4 is modulated over time from the start of the fifth step so that the ultrasonic vibration becomes stronger continuously or intermittently, and once it reaches the set ultrasonic vibration strength, the fifth step may be ended, the ultrasonic vibration strength may be maintained constant before weakening, or the ultrasonic vibration strength may be maintained constant or weakened. In the profile in FIG. 18, the fourth strength US4 increases linearly from the strength of the second strength US2.

Applying the fifth load P5 deforms the bump 22, further deforming (shape-collapsing) its height which was already bonded with the pad 11 during the second step. The height H_{F} of the bump 22 which changes during the fifth step is calculated as [distance H5 at the end of the second step]−[distance H8 at the end of the fifth step].

A maximum value of the fifth load P5 is preferably more than the maximum value of the first load P1. The maximum value of the fifth load P5 is preferably 40% or more and 120% or less, more preferably 60% or more and 100% or less, and even more preferably 70% or more and 90% or less of the maximum value of the first load P1.

The average value of the fifth load P5 is preferably less than the average value of the first load P1. The average value of the fifth load P5 is preferably 40% or more and 120% or less, more preferably 60% or more and 100% or less, even more preferably 70% or more and 90% or less of the average value of the first load P1.

The maximum value of the fifth load P5 is preferably more than the maximum value of the second load P2. The maximum value of the fifth load P5 is preferably 100% or more and 600% or less, more preferably 200% or more and 500% or less, and even more preferably 250% or more and 450% or less of the maximum value of the second load P2.

The average value of the fifth load P5 is preferably more than the average value of the second load P2. Preferably, the average value of the fifth load P5 is 100% or more and 600% or less, more preferably 200% or more and 500% or less, even more preferably 250% or more and 450% or less of the average value of the second load P2.

A maximum value of the fourth strength US4 is preferably 800% or more and 1700% or less, more preferably 1000% or more and 1500% or less, and even more preferably 1100% or more and 1400% or less of the maximum value of the first strength US1.

The maximum value of the fourth strength US4 is preferably 70% or more and 130% or less, more preferably 80% or more and 120% or less, even more preferably 90% or more and 110% or less of the maximum value of the second strength US2.

The average value of the fourth strength US4 is preferably 800% or more and 1700% or less, more preferably 1000% or more and 1500% or less, and even more preferably 1100% or more and 1400% or less of the average value of the first strength US1.

The average value of the fourth strength US4 is preferably 70% or more and 130% or less, more preferably 80% or more and 120% or less, and even more preferably 90% or more and 110% or less of the average value of the second strength US2.

In the fourth embodiment, the height HB of the bump 22 deformed during the second step is preferably 0 [μm] or more and 7 [μm] or less, more preferably 0 [μm] or more and 5μm or less, and even preferably 0 [μm] or more and 3 [μm] or less.

The height HF of the bump 22 which changes during the fifth step is preferably less than 50%, more preferably 30% or less, an even more preferably 20% or less of the total height (H_{A}+H_{B}+H_{F}) of the bump 22 deformed during the first step, the second step and the fifth step.

The height HF of the bump 22 which changes during the fifth step is preferably 5% or more and less than 50%, more preferably 5% or more and 30% or less, and even more preferably 5% or more and 20% or less of the total height (H_{A}+H_{B}+H_{F}) of the bump 22 deformed during the first step, the second step and the fifth step.

The height H_{F} of the bump 22 changing in the fifth step is preferably 5% or more and less than 50%, more preferably 5% or more and 30% or less, and even more preferably 5% or more and 20% or less of the height (H_{A}) of the bump 22 deformed during the first step.

Preferably, the temperature of the bump 22 during the first step, the second step, and the fifth step is a temperature equal to or below the melting point of the bump 22. It is preferable that the temperatures of the bump 22 in the second step and the fifth step are higher than the temperature of the bump 22 in the first step.

It is preferable that the bump 22 is deformed slightly by applying the fifth load P5 with a strong load. By further deforming (shape-collapsing) the bump 22 after bonding with applying ultrasonic vibration, it is possible to bond and deform the bump 22 and the pad 11 more reliably.

### Fifth Embodiment

A fifth embodiment relates to a manufacturing method for the semiconductor device 100. The fifth embodiment is a variant in which a sixth step and a seventh step are added to the manufacturing methods for the semiconductor device 100 of the first to fourth embodiments. The sixth step can also be performed after the second step of the second embodiment. Descriptions common to the fifth embodiment and the first to fourth embodiments will be omitted.

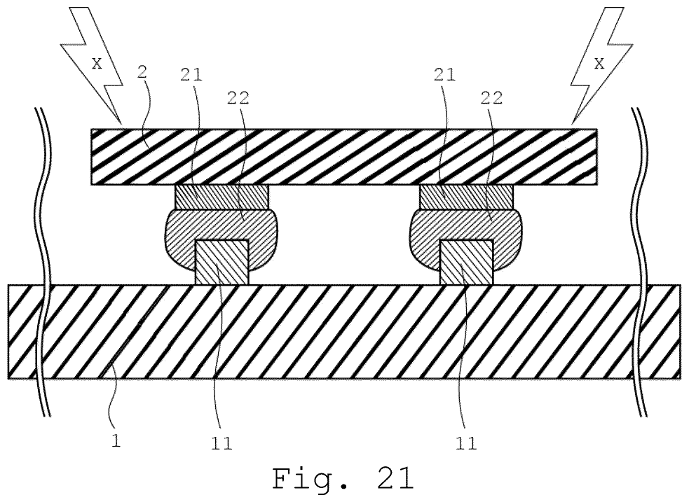

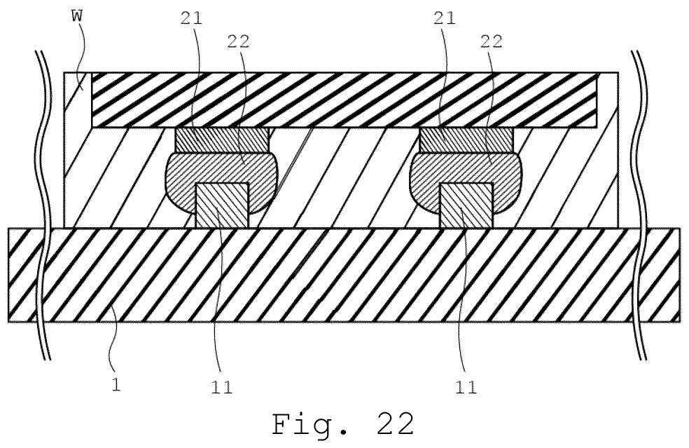

FIG. 20 shows a flowchart of the manufacturing method for the semiconductor device 100. The manufacturing method for the semiconductor device 100 in the fifth embodiment, referring to FIG. 21 and FIG. 22 illustrating schematic diagrams of the manufacturing method for the semiconductor device 100, will be described. The manufacturing method for the semiconductor device 100 in the fifth embodiment further comprises a sixth step, after the second step, after the fourth step, or after the fifth step, heating the semiconductor element 2 and the circuit board 1 and a seventh step, after the sixth step, cleaning a member in which the heating is processed.

The sixth step is performed after the processing of the first to fourth embodiments is completed, meaning after the deformation of the bump 22 and the bonding of the bump 22 and the pad 11 are completed.

In the sixth step, as shown in the schematic diagram of FIG. 21, heat X is applied to the semiconductor element 2 and the circuit board 1. Specifically, in the sixth step, the process of heating the bonded semiconductor element 2 and circuit board 1 using an oven or the like is performed to promote the growth of the alloy layer of the bonded bump 22 and pad 11. The growth of the alloy of the bonded bump 22 and pad 11 improves the bonding strength, contributing to the improvement in reliability of the semiconductor device 100.

It is preferable that the processing temperature (the temperature of the bump 22) during the sixth step be equal to or below the melting point of the bump 22. In view of effectively promoting alloy growth in the sixth step, the processing temperature is preferably 80[°C.] or more. When flux is applied to the bump 22 and/or the pad 11 before the first step or the third step, the processing temperature in the sixth step is preferably 150[°C.] or less in view of preventing burning of the flux during the heating process.

The processing temperature in the sixth step is preferably 80° C. or more and 150° C. or less.

A heating process duration in the sixth step is preferably 15 [min] or more for promoting alloy growth. The heating process duration is preferably 10 [hrs] or less in view of preventing burning of the flux. The heating process duration in the sixth step is preferably 15 [min] or more and 10 [hrs] or less.

It is preferable to perform the seventh step, particularly when flux is used. In the seventh step, as shown in the schematic diagram of FIG. 22, a cleaning liquid W is used to clean the member in which heating is processed in the sixth step. An alkaline cleaning solution, acetone, or isopropyl alcohol is preferred as the cleaning liquid W. Since the bump 22 and the pad 11 are strongly bonded together by the sixth step, the bond between the bump 22 and the pad 11 is less likely to be broken due to cleaning pressure during the seventh step.

The reliability of the bonded portion between the bump 22 and the pad 11 is improved by the heating process in the sixth step, contributing to the improvement in reliability of the semiconductor device 100. Since the reliability of the bonded portion between the bump 22 and the pad 11 is improved even when cleaning is performed in the seventh step after the sixth step, the bonded portion is less likely to be broken due to cleaning pressure. This contributes to both the improvement in reliability and yield of the semiconductor device 100.

While certain embodiments have been described, these embodiments have been presented by way of example only, and are not intended to limit the scope of the inventions.

Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method for a semiconductor device comprising:
a first step deforming a bump of a semiconductor element by applying a first load to the semiconductor element to press the bump onto a circuit board and applying either no ultrasonic vibration or ultrasonic vibration with a first strength to the bump; and
a second step, after the first step, bonding the bump to a pad of the circuit board by applying a second load to the semiconductor element to press the bump and applying ultrasonic vibration with a second strength stronger than the first strength to the bump.

2. The manufacturing method according to claim 1, wherein
the ultrasonic vibration of the first step is not applied to the bump in the first step.

3. The manufacturing method according to claim 1, wherein
a maximum value of the first load is 100% or more and 250% or less of a maximum value of the second load.

4. The manufacturing method according to claim 1, wherein
a maximum value of the first strength is 0% or more and 70% or less of a maximum value of the second strength.

5. The manufacturing method according to claim 1, wherein
a height of the bump which changes during the first step, is 30% or more of the total height of the bump deformed in the first step and the second step.

6. The manufacturing method according to claim 1, wherein
a height of the bump which changes during the first step, is 60% or more and 100% or less of the total height of the bump deformed in the first step and the second step.

7. The manufacturing method according to claim 1, wherein
a height of the bump which changes during the second step, is 0% or more and 200% or less of a height of the bump deformed in the first step.

8. The manufacturing method according to claim 1, wherein
the bump is deformed by applying ultrasonic vibration with the first strength before applying the first load.

9. The manufacturing method according to claim 1, further comprising a third step deforming the bump by applying a third load to the semiconductor element to press the bump onto the circuit board and applying ultrasonic vibration with a third strength which is weaker than the second strength to the bump.

10. The manufacturing method according to claim 9, wherein
a height of the bump which changes during the third step, is 50% or less of a total height of the bump deformed in the first step, second step, and the third step, and
a height of the bump which changes during the first step, is 30% or more of the total height of the bump deformed in the first step, second step, and the third step.

11. The manufacturing method according to claim 9, wherein
a maximum value of the third strength is more than 0% or more and 100% or less of a maximum value of the second strength.

12. The manufacturing method according to claim 9, wherein
a maximum value of the third strength is 400% or more and 900% or less of a maximum value of the first strength.

13. The manufacturing method according to claim 9, wherein
a maximum value of the third load is 10% or more and 60% or less of a maximum value of the first load.

14. The manufacturing method according to claim 1, further comprising a fourth step, after the second step, deforming the bump by applying a fourth load to the semiconductor element to press the bump without applying ultrasonic vibration to the bump, wherein
a maximum value of the fourth load is 300% or more and 1200% or less of a maximum value of the first load.

15. The manufacturing method according to claim 14, wherein
a height of the bump which changes during the fourth step is less than 50% of a total height of the bump deformed during the first step, the second step, and the fourth step, and
a height of the bump which changes during the first step is 30% or more of the total height the bump deformed during the first step, the second step, and the fourth step.

16. The manufacturing method according to claim 1, further comprising a fifth step, after the second step, deforming the bump by applying the fifth load to the semiconductor element to press the bump of the semiconductor element onto the circuit board and by applying ultrasonic vibration with a fourth strength to the bump, wherein
a maximum value of the fifth load is 40% or more and 120% or less of a maximum value of the first load. 17, The manufacturing method according to claim 16, wherein
a height of the bump deformed during the fourth is less than 50% of a total height of the bump deformed during the first step, the second step, and the fifth step, and
a height of the bump deformed during the first is less than 50% of the total height of the bump deformed during the first step, second step, and the fifth step.

18. The manufacturing method according to claim 16, wherein
the temperature of the bump during the first step is equal to or below the melting point of the bump,
the temperature of the bump during the second step is equal to or below the melting point of the bump,
the temperature of the bump during the third step is equal to or below the melting point of the bump,
the temperature of the bump during the fourth step is equal to or below the melting point of the bump, and
the temperature of the bump during the fifth step is equal to or below the melting point of the bump.

19. The manufacturing method according to claim 16, further comprising a sixth step, after the fifth step, heating the semiconductor element and the circuit board.

20. The manufacturing method according to claim 19, further comprising a seventh step, after the sixth step, cleaning the heated member, wherein
the heating temperature during the sixth step is equal to or below the melting point of the bump.
